(19) United States
(12) Patent Application Publication
(10) Pub. No.: US 2007/0139888 A1
(43) Pub. Date: Jun. 21, 2007

(54) Heat transfer system

(75) Inventors: Brian A. Hamman, (US); Arthur W. Fisher, (US)

Correspondence Address: Arthur W. Fisher;Patent Dominion Partnership, LP, 6103 Twin Oaks Circle, Dallas, TX, 75240, US

(73) Assignee: QNX Cooling Systems, Inc.

(21) Appl. No.: 11/303,566

(22) Filed: Dec. 19, 2005

(51) Int. Cl. H05K 7/20

(52) U.S. Cl. 361/701

(57) ABSTRACT

Heat transfer units for use with cooling systems are presented. A number of embodiments are presented. In each embodiment a heat transfer unit is depicted wherein the flow of coolant through the unit is distributed and/or regulated to increase the efficiency of thermal transfer from heat generating components in an electronic system thermally coupled to the heat transfer unit to a coolant flowing through the heat transfer unit.

### BACKGROUND OF THE INVENTION

1. Cross Reference to Related Applications

Reference is made to pending U.S. patent application Ser. No. 10/688,587 filed Oct. 18, 2003 for a detailed description of a cooling systems and various heat transfer units and heat exchangers and their operation.

2. Description of the Related Art

At the heart of data processing and telecommunication devices are processors and other heat-generating components which are becoming increasingly more powerful and generating increasing amounts of heat. As a result, more powerful cooling systems are required to prevent these components from thermal overload and resulting system malfunctions or slowdowns.

Traditional cooling approaches such as heat sinks and heat pipes are unable to practically keep up with this growing heat problem. Cooling systems which use a liquid or gas to cool these heat generating components are becoming increasingly more needed and viable. These systems utilize heat transfer units thermally coupled to the heat generating components for absorbing or extracting heat from the heat generating components into a coolant flowing there through. The coolant, now heated is directed to a heat exchanger where heat is dissipated from the coolant, creating cooled coolant and return to the heat transfer unit to repeat the cycle.

Distributing and regulating the flow of coolant through the heat transfer unit is desirable. Most heat generating components have “hot spots” where, as necessitated by the design of the component, concentrations of heat will build up. These “hot spots” can be accurately predicted from the design. Many chip manufacturers have used thermal spreaders to more evenly distribute the heat over the surface of the chip. They have also employed the use of thermal throttling circuitry which senses the internal chip temperature and slows down or even shuts down the operation of the chip when a certain temperature is reached.

This has become a virtually necessity when heat sinks or heat pipes are used. Whether heat spreaders are used or not, it is still desirable to insure a distribution of coolant flow over the heat transferring surfaces. Moreover, it may often be desirable to regulate the flow of coolant such that more coolant flow occurs in or over areas adjacent to the “hot spots” or hooter parts of chip surface.

Thus, there is a need in the art for a method and apparatus for more effectively cooling these heat generating components in data processing and telecommunication systems. There is a need in the art for an optimal, cost-effective method and apparatus for cooling heat generating components which allows the processor or other heat-generating component to operate at the marketed operating capacity or greater. There is also a need in the art for a method and apparatus for distributing and/or regulating the flow of coolant through a heat transfer unit for increasing the efficiency of the cooling system.

### SUMMARY OF THE INVENTION

A method and apparatus for distributing the flow of coolant through a heat transfer system by creating coolant pathways through the heat transfer unit.

A method and apparatus for regulating the flow of coolant through the coolant pathways by varying the size of the coolant pathways.

A method and apparatus for regulating the flow of coolant through a heat transfer unit by adjusting the flow of the coolant entering into or leaving the pathways.

A data processing system having heat transfer units which regulate and/or regulate the flow of coolant there through.

A motherboard having heat transfer units which regulate and/or regulate the flow of coolant there through.

A telecommunications system having heat transfer units which regulate and/or regulate the flow of coolant there through.

An optical device having heat transfer units which regulate and/or regulate the flow of coolant there through.

A device having a processor and having heat transfer units which regulate and/or regulate the flow of coolant there through.

### BRIEF DESCRIPTION OF THE DRAWINGS

FIG. 1A is a top view of the contact surface of the heat transfer unit with dividers extending upwards there from.

FIG. 1B is a 3-dimensional view of the housing of the heat transfer unit less the contact surface.

FIG. 1C is a side, cross-sectional view of the contact surface shown in FIG. 1A.

FIG. 2A is a top view of the contact surface of the heat transfer unit with dividers extending upwards there from with a cross-sectional view of the flow adjusters.

FIG. 2B is a side, cross-sectional view of the flow adjusters.

FIG. 2C is a side, cross-sectional view of the contact surface shown in FIG. 2A.

FIG. 3A is a top view of the contact surface of the heat transfer unit with dividers extending upwards there from with a cross-sectional view of an inlet manifold with flow adjusters and an outlet manifold

FIG. 3B is a side, cross-sectional view of the inlet manifold with the flow adjusters.

FIG. 4 is a depiction of a cooling system with the heat transfer unit there in.

### DETAILED DESCRIPTION

While the making and using of various embodiments of the present invention are discussed in detail below, it should be appreciated that the present invention provides many applicable inventive concepts, which can be embodied in a wide variety of specific contexts. The specific embodiments discussed herein are merely illustrative of specific ways to make and use the invention and do not limit the scope of the invention.

It should be understood that the principles and applications disclosed herein can be applied in a wide range of data processing systems, telecommunication systems and other systems. In the present invention, heat produced by a heat generating component such as a microprocessor in a data processing system is transfer to a coolant in a heat transfer unit and dissipated in the cooling system. Liquid cooling solves performance and reliability problems associated with heating of various heat generating components in electronic systems.

The present invention may be utilized in a number of computing, communications, and personal convenience applications. For example, the present invention could be implemented in a variety of servers, workstations, exchanges, networks, controllers, digital switches, routers, personal computers which are portable or stationary, cell phones, and personal digital assistants (PDAs) and many others.

The present invention is equally applicable to a number of heat-generating components (e.g., central processing units, optical devices, data storage devices, digital signal processors or any component that generates significant heat in operation) within such systems. Furthermore, the dissipation of heat in this cooling system may be accomplished in any number of ways by a heat exchange unit of various designs, but which are not discussed in detail in this application. The present invention may even be combined with a heat exchanger as part of a single unit to constitute the entire cooling system.

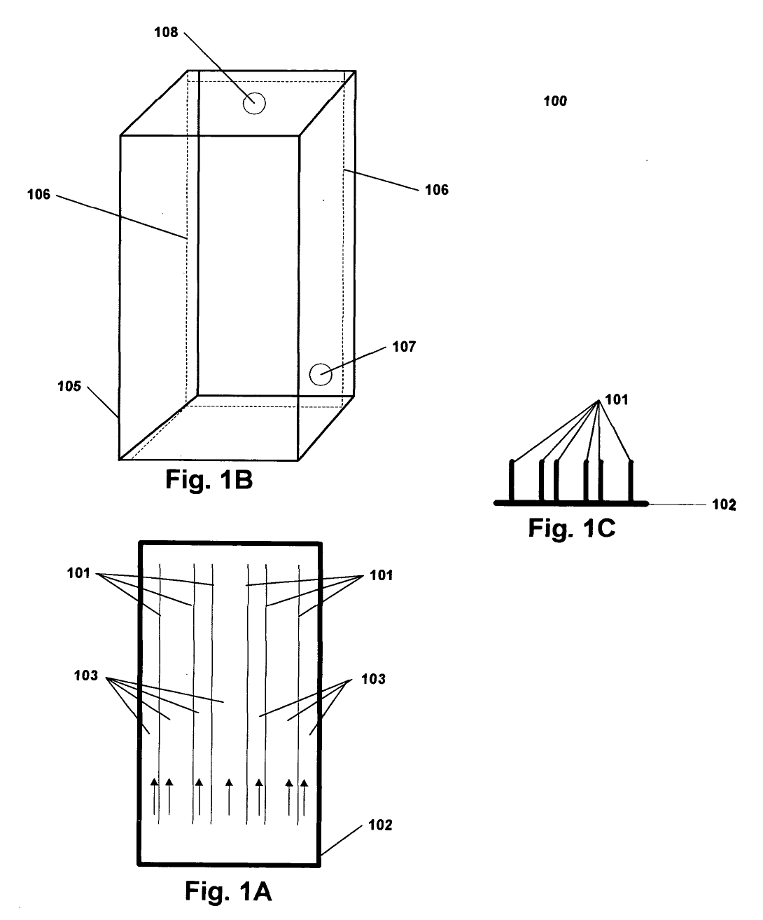

Referring now to FIGS. 1A, 1B & 1C a heat transfer unit 100 embodying the present invention is depicted. In FIG. 1A, a contact surface 102 is depicted with a plurality of divider walls 101 extending upward there from. FIG. 1C is a side, cross-sectional view of the contact surface 102 and the divider walls 101. The contact surface 102 is coupled to housing 105 in FIG. 1B to form the heat transfer unit 100 with a sealed cavity for coolant flow there through. When combined, the divider walls extend into the cavity of housing 105. The divider walls 101 may also be part of the housing 105 extending from the top inside surface there of to the contact surface 102.

The housing 105 also includes an inlet 107 and an outlet 108. The inlet 107 receives cooled coolant from a heat exchanger (not shown) for directing the coolant through the cavity of the housing 105. The outlet 108 receives heated coolant from the cavity of the housing 105 and directs it back to the heat exchanger for cooling and to repeat the cycle. The heat exchanger receives heated coolant from the heat transfer unit 100, dissipates heat from the coolant, and returns cooled coolant to the heat transfer unit 100.

The housing 105 may also includes flanges 106 for receiving the contact surface 102 and fastening thereto. The housing may also have clip posts or the like (not shown) extending from the exterior surfaces thereof so that the heat transfer unit may be further secured to the heat generating components in the electronic system by clips, for example, extending from a motherboard to which the heat generating components are attached.

The contact surface 102 can be a thin piece of heat conducting material, such as copper. The divider walls 101 can be made of any material, but a material with good thermal transfer characteristics is preferable. The thickness of these divider walls should be thin to expose as much of the top surface of the contact surface 102 to coolant flowing through the heat transfer unit 100.

The bottom side of the contact surface 102 will be thermally coupled to one or more heat-generating components by any number of means including, but not limited to a thermal paste. The contact surface 102 may be fastened or coupled to the housing 105 before being thermally coupled to the heat generating components. Alternatively, the contact surface may be thermally coupled and secured to the heat generating components first and the housing 105 connected to it at a later time in the assembly process.

The function of the divider walls 101 is to ensure the coolant flowing through the cavity of the housing is appropriately distributed across the top surface of the contact surface 102. The divider walls 101 may be evenly spaced to provide relatively even flow of coolant across contact surface 102. However, many heat generating components are known to have “hot spots” where the concentration of heat is greatest. In such cases, it may be desirable to vary the spacing between divider walls to allow more coolant flow across portions of contact surface which will be adjacent to the “hot spots”.

As cooled coolant enters the cavity of the housing through inlet 107, it is directed across the contact surface 102 in the manner desired through channels or coolant pathways formed by divider walls 101. Heat from the heat generating components is transferred through contact surface 102 and absorbed into the coolant flowing there over. Then coolant becomes heated and flows on to the outlet 108 where it is directed to a heat exchanger for cooling.

As mentioned above, the divider walls may be disposed from the top, interior surface of the housing 105. In such circumstances, it may be desirable to eliminate the contact surface 102 and thermally couple and secure the housing 105 to a surface of the heat generating components or to a heat spreader attached to the heat generating components. This allows for direct contact of the coolant with the surface of the heat generating components increasing the transfer of heat from the components to the coolant by eliminating the thermal resistance of the contact surface 102.

Whenever possible, it is desirable to orient the heat transfer unit 100 so that the inlet 107 is situated below the outlet 108. This orientation allows the cooling system to take advantage of convective circulation of the coolant since heated coolant will naturally rise and cooled coolant will naturally drop. In this manner, the thermodynamics of the coolant can assist forced circulation, by a pump for example, and provide additional cooling of the heat generating components even after power is shut down to the electronic system.

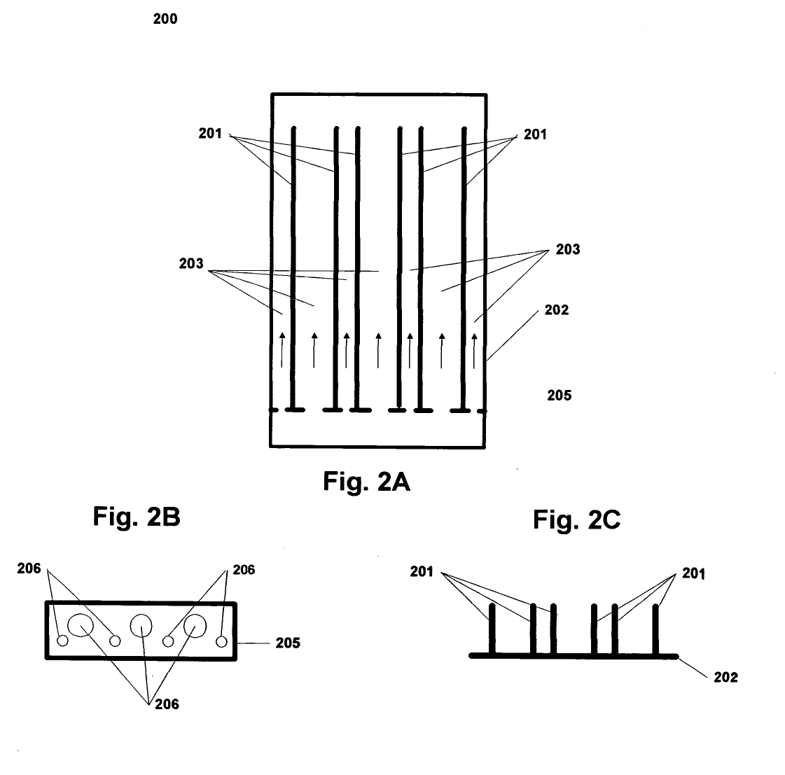

FIGS. 2A, 2B & 2C depict another embodiment of the present invention and specifically, the introduction of coolant flow adjusters. FIG. 2A is top, cross-sectional view of a contact surface 202 of the heat transfer unit 200. Divider walls 201 are shown extending upward from the surface 202. Also depicted is a cross-sectional view of a flow adjuster assembly 202 in close proximity to the start of the divider walls 201 and with openings there through to allow coolant to flow into the cavity formed with a housing (not shown) similar to that of FIG. 1B.

FIG. 2B is a side view of the flow adjuster assembly 205. As depicted in FIG. 2B, a series of holes or openings 206 through the assembly 205 comprise the flow adjusters. Coolant received from the inlet of the housing must pass through the flow adjusters 206 before entering the channels or pathways created by the divider walls 201. The size of the holes or openings of the flow adjusters 206 may be uniform or may vary as shown in FIG. 2B. As mentioned above, it may be desirable to provide more coolant flow through a channel adjacent to known “hot spots” of the heat generating components. By having a larger opening through the flow adjuster assembly 205, more coolant flow will occur.

It will be appreciated that the flow adjusters 206 depicted herein are just one embodiment of the present invention and many other techniques are available for adjusting the flow within the purview of the present invention.

FIG. 2C is a side, cross-sectional view of the contact surface 202 depicting the divider walls 201. The spacing of the divider walls may be uniform or varied as shown in FIGS. 2A and 2C.

The divider walls 201 and the flow adjuster assembly 205 may also be disposed from the top interior surface of a housing, similar to housing 105, and the contact surface 202 may be eliminated for direct exposure of the coolant to the heat generating components.

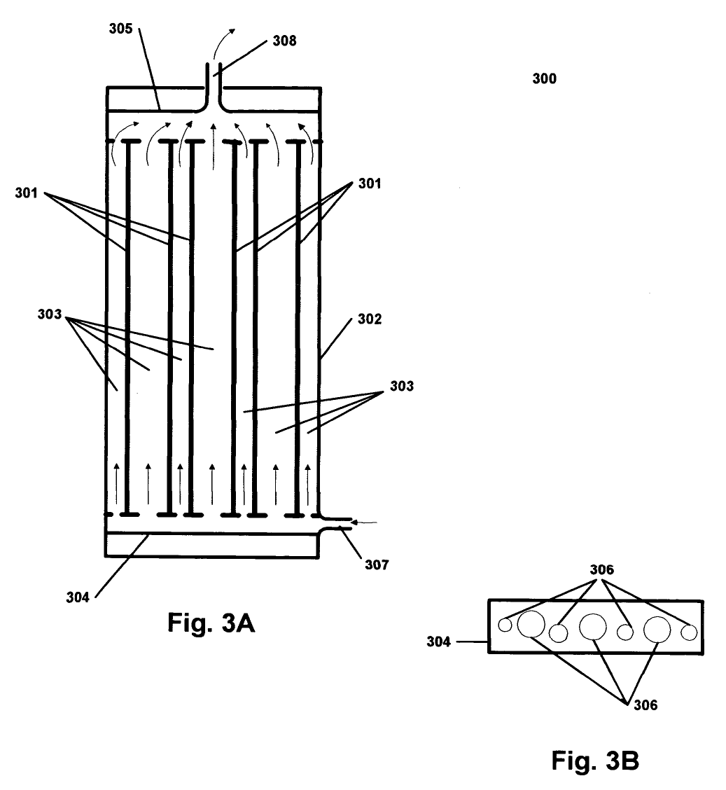

In FIGS. 3A and 3B represent yet another embodiment of the present invention. In FIG. 2A, the contact surface 302 of the heat transfer unit 300 is depicted in a top, cross-sectional view. Divider walls 301 form the channels or pathways for coolant through the cavity formed by the contact surface 302 and a housing, not shown, similar to that of FIG. 1B. Additionally, an inlet manifold 304 with an inlet 307 and an outlet manifold 305 with an outlet 308 are shown. FIG. 3B is a side, cross-sectional view of the inlet manifold 304 with flow adjusters 306.

The inlet manifold 304 and the outlet manifold 305 may be of any shape, such as a cylinder, and the flow adjusters 306 may be openings or holes or other devices for regulating the flow of the coolant through the channels or pathways formed by the divider walls 301. The size of the openings of the flow adjusters 306 may be uniform or may vary as shown in FIG. 3B to differentiate the flow of coolant through different channels or pathways. Similarly, the spacing between the divider walls 301 may be uniform or may vary.

In operation, cooled coolant enters the inlet 307 and then into inlet manifold 304. The coolant is then directed into the channels formed by the divider walls 301 through the flow adjusters 306. After passing through the channels or pathways, absorbing heat from the heat generating units, and becoming heated coolant, the coolant passes into the outlet manifold 305 where it is directed to the outlet 308 and then to a heat exchanger, not shown, for cooling and then repetition of the cycle.

It will be appreciated that the outlet manifold 305 is optional. Moreover, openings in the outlet manifold 305 to receive the heated coolant may be uniform or may vary. Additionally, the inlet manifold 304 may be eliminated and the outlet manifold used to regulate the flow of coolant.

The inlet 307 and the outlet 308 may be detachable for ease of assembly. For example, both the inlet 307 and the outlet 308 may have threaded cylinders at the ends thereof for passing through an opening in the housing and threading into the inlet manifold 304 and outlet manifold 305, respectively. Grommets and other simple devices may be used to insure a sealed connection and no leakage.

The divider walls 301, the inlet manifold 304, the inlet 307, the output manifold 305 and the outlet 308 may all be attached to the inside of the housing, not shown, to facilitate assembly and/or to eliminate the contact surface 302.

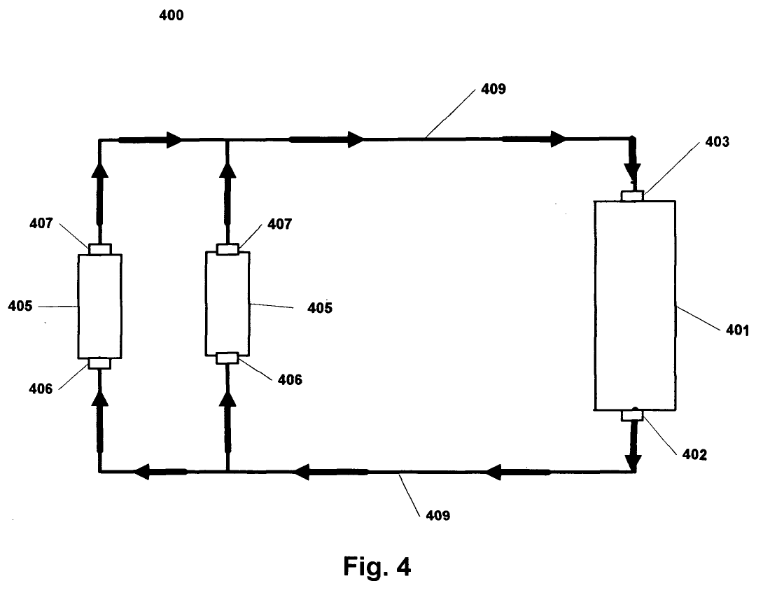

FIG. 4 represents a schematic diagram of a complete cooling system 400 with the heat transfer unit of the present invention. Heat transfer units 405 may be any one of the embodiments of the present invention or a combination of embodiments of the heat transfer units of the present invention and other heat transfer units. Each heat transfer unit 405 has an inlet 406 and an outlet 407. Heat exchanger 401 has an inlet 403 and an outlet 402 and is coupled to the heat transfer units 405 by means of a coolant transport system 409, such as conduits, for example. It will be understood that any number and type of heat exchanger units may be employed with the heat transfer units of the present invention including heat exchanger units with and without reservoirs; with or without a pump; and with or without fans or other air flow devices.

The heat exchanger 401 receives heated coolant from the heat transfer units 405 at its inlet 403. The heat exchanger then dissipates heat from the coolant, creating cooled coolant which is directed to the outlet 402 and on to the inlets 406 of the heat transfer units 405 through the transport system 409 as shown by the directional arrows. The heat transfer units 405 absorb heat from the heat generating components of the electronic system into the coolant, creating heated coolant and directs the heated coolant back to the heat exchanger 401, through the outlets 407 and the coolant transport system 409.

Any number of coolants, liquid or gas, may be used with the present invention such as, for example, a propylene glycol based coolant.

In FIG. 4, the inlets 406 of the heat transfer units are shown disposed below the outlets 407. Similarly, the inlet 403 of the heat exchanger 401 is shown above the outlet 402. Disposition of inlets and outlets in this manner, when possible, maximizes convective circulation of the coolant through the system to enhance the forced circulation of the coolant during normal operation with power and to provide cooling after power shut down to the electronic system.

Thus, the present invention has been described herein with reference to particular embodiments for particular applications. Those having ordinary skill in the art and access to the present teachings will recognize additional modifications, applications, and embodiments within the scope thereof.

It is, therefore, intended by the appended claims to cover any and all such applications, modifications, and embodiments within the scope of the present invention.

What is claimed is:

1. A cooling system for cooling heat-generating components in an electronic system having one or more heat transfer units, the heat transfer units comprising:
a housing thermally coupled to one or more heat-generating components and having a cavity there in for a coolant to flow there through;
a heat transfer unit inlet for receiving cooled coolant and directing the cooled coolant to the cavity;
dividers within the housing for forming coolant pathways through the cavity and ensuring a distribution of coolant flow through the cavity; and
a heat transfer unit outlet for receiving heated coolant from the cavity and directing the heated coolant out of the eat transfer unit; and
wherein the coolant flows through the coolant pathways of the cavity and removes heat from the heat-generating components by absorbing such heat into the coolant and creating heated coolant.

2. The cooling system as set forth in claim 1 wherein the housing has a surface which is open or partially open and such open or partially open surface is thermally coupled to surfaces of one or more heat-generating components and wherein the dividers are connected to an interior surface of the housing oppositely disposed to the open or partially open surface of the housing and wherein the coolant comes into direct contact with the surfaces of the heat-generating components as it flows through the coolant pathways.

3. The cooling system as set forth in claim 1 further comprising coolant flow adjusters disposed at the entrance to the liquid pathways for adjusting the flow of the coolant through the liquid pathways.

4. The cooling system as set forth in claim 3 wherein the coolant flow adjuster is comprised of an inlet to the coolant pathway having an opening whose size is varied to achieve the desired flow.

5. The cooling system as set forth in claim 1 further comprising:
a coolant manifold for receiving cooled liquid from the heat transfer unit inlet and distributing the coolant to the coolant pathways.

6. The cooling system as set forth in claim 5 wherein the coolant manifold further comprises:
coolant flow adjusters for adjusting the flow of coolant through the coolant pathways.

7. The cooling system as set forth in claim 5 wherein the coolant flow adjusters comprise:
outlets coupling the coolant manifold to the liquid pathways, each outlet having an opening whose size is varied to achieve the desired flow through the coolant pathway.

8. The cooling system as set forth in claim 1 further comprising:
a coolant manifold for receiving heated coolant from the coolant pathways and directing the heated coolant to the heat transfer unit outlet.

9. The cooling system as set forth in claim 1 further comprising;
a heat exchange unit for receiving heated coolant from the heat transfer units, cooling the coolant by dissipating heat from the coolant and generating cooled coolant for transporting to the heat transfer units; and
means for transporting heated coolant from the heat transfer units to the heat exchange unit and transporting cooled coolant from the heat exchange unit to the heat transfer units.

10. The cooling system as set forth in claim 1 wherein the heat transfer inlet is disposed below the heat transfer unit outlet to enhance convective circulation of the coolant.

11. A data processing system having the cooling system of claim 1.

12. A motherboard having the cooling system of claim 1.

13. A telecommunications system having the cooling system of claim 1.

14. An optical device having the cooling system of claim 1.

15. A device having one or more processors and having the cooling system of claim 1.

16. A method of cooling heat-generating components in an electronic system having one or more heat transfer units, each heat transfer unit thermally coupled to surfaces of one or more heat-generating components, the method comprising the steps of:
receiving cooled coolant at the heat transfer unit;
transporting the cooled coolant through liquid pathways in the heat transfer unit, the cooling absorbing heat from the heat-generating components as it flows through the coolant pathways and creating heated coolant; and
directing the heated coolant from the coolant pathways out of the heat transfer unit.

17. The method of cooling as set forth in claim 16 further comprising the step of:
adjusting the flow of coolant through each coolant pathway.

18. The method of cooling as set forth in claim 16 wherein the heat transfer unit has a surface which is open or partially open and such open or partially open surface is thermally coupled to surfaces of one or more heat-generating components and wherein dividers are connected to an interior surface of the housing oppositely disposed to the open or partially open surface of the housing forming coolant pathways through the heat transfer unit, the method further comprising the step of:
having the coolant directly contact the surfaces of the heat-generating components as it flows through the coolant pathways.

19. A method of cooling as set forth in claim 16 wherein the heat transfer unit has an inlet for receiving cooled coolant and an outlet for receiving heated coolant from the coolant pathways, the method further comprising the step of:
positioning the inlet below the outlet to enhance convective circulation.

20. A method of cooling as set forth in claim 16, the method further comprising the steps of:
transporting the heated coolant from the heat transfer units to a heat exchange unit;
cooling the heated coolant in the heat exchange unit by dissipating heat from the coolant and creating cooled coolant; and
transporting the cooled coolant from the heat exchange unit to the heat transfer units.
